(19) United States
(12) Patent Application Publication
(10) Pub. No.: US 2007/0096226 A1
(43) Pub. Date: May 3, 2007

(54) MOSFET dielectric including a diffusion barrier

(76) Inventors: Chun-Li Liu, Mesa, AZ (US); Tushar P. Merchant, Gilbert, AZ (US); Marius K. Orlowski, Austin, TX (US); James K. Schaeffer, Austin, TX (US); Matthew W. Stoker, Mesa, AZ (US)

Correspondence Address: INGRASSIA, FISHER & LORENZ, P.C., 7150 E. CAMELBACK ROAD, SUITE 325, SCOTTSDALE, AZ, 85251, US

(21) Appl. No.: 11/264,069

(22) Filed: Oct. 31, 2005

(51) Int. Cl. H01L 29/94; H01L 29/76; H01L 31/00

(52) U.S. Cl. 257/411

(57) ABSTRACT

A semiconductor device includes a substrate, a multilayered assembly of high k dielectric materials formed on the substrate, and a first conducting material formed on the upper layer of the assembly of high k dielectric materials. The multilayered high k dielectric assembly includes a lower layer, an upper layer, and a diffusion barrier layer formed between the lower and upper dielectric layers. The diffusion barrier layer has a greater affinity for oxygen than the upper and lower layers. The first conducting layer includes a conducting compound of at least a metal element and oxygen.

### TECHNICAL FIELD

The present invention relates to metal oxide semiconductor field-effect transistors (MOSFETs), and more specifically relates to materials for forming gate dielectric layers in MOSFETs.

### BACKGROUND

A MOSFET gate structure commonly includes a polysilicon electrode separated from a substrate by a dielectric material. Transistor structures are becoming increasingly small, and the scaling of the MOSFET channel length to submicron feature sizes requires a corresponding reduction in the gate dielectric thickness to achieve high performance and to control short channel effects. Although SiO₂ is largely considered the gate dielectric material of choice, this material is fast approaching its thinness limit. As SiO₂ is reduced in thickness to about 2.5 nm, a gate leakage current may begin to flow across the dielectric due to direct tunneling. One solution to this problem is to use a thicker film of a high dielectric constant material, hereinafter “high k dielectric material,” that produces a large capacitance across the gate while reducing the tunneling current. An additional advantage of high k dielectric materials is that they tend to be effective diffusion barriers against gate electrode dopants. High k dielectric materials have a dielectric constant above 3.9, which is the dielectric constant for silicon dioxide. Some high k dielectric materials include compounds of oxygen such as hafnium dioxide (HfO₂), zirconium dioxide (ZrO₂), and titanium dioxide (TiO₂), among others.

The use of high k dielectric materials affects other components in the transistor structure. For example, a thin silicon oxide layer tends to form during deposition of a high dielectric constant oxide material on a silicon substrate. However, silicon oxide layer formation is difficult to control. It is desirable that the interfacial silicon dioxide layer be as thin as possible to minimize its adverse impact on the effective oxide thickness for the dielectric material.

Also, an N- or P-doped polysilicon electrode for NMOS and PMOS applications, respectively may not have the appropriate work function for fully depleted semiconductor-on-insulator (SOI) or double gated MOSFET devices. Further, the vacuum work function of the gate electrode is shifted when the gate electrode materials contact high dielectric constant materials. The shift of the vacuum work function to an effective work function can be as large as 0.7 eV. One class of conducting materials that has proven to achieve a high work function when stacked with a high dielectric constant material includes conductive metal oxides, oxynitrides, oxysilicides, and other oxygen-containing metallic compounds. However, when annealing the deposited conducting and dielectric materials, some oxygen from the conducting material is believed to leak through the dielectric material and the thin silicon oxide layer. The oxygen then reacts with the silicon substrate and forms an additional interfacial silicon oxide layer between the substrate and the silicon oxide formed during deposition of the dielectric material on the substrate. The increased interfacial layer detrimentally increases the effective oxide thickness for the dielectric material, which in turn negatively impacts transistor performance.

In view of the challenges associated with oxygen leakage during the annealing step, there is a need for a MOSFET gate stack configuration that prevents leakage from an oxygen-rich conducting material into an underlying substrate. Furthermore, other desirable features and characteristics of the present invention will become apparent from the subsequent detailed description and the appended claims, taken in conjunction with the accompanying drawings and the foregoing technical field and background.

### BRIEF DESCRIPTION OF THE DRAWINGS

The present invention will hereinafter be described in conjunction with the following drawing figures, wherein like numerals denote like elements, and

FIG. 1 is a cross-sectional side view of a MOSFET that includes a dielectric assembly that incorporates a diffusion barrier according to an embodiment of the invention;

FIG. 2 is a cross-sectional side view of a box having a silicon substrate formed thereon between two shallow trench isolation structures, and a silicon oxide film formed on the substrate;

FIG. 3 is a cross-sectional side view of the assembly of FIG. 2, further including a lower dielectric layer formed on the silicon oxide layer;

FIG. 4 is a cross-sectional side view of the assembly of FIG. 3, further including a diffusion barrier dielectric layer formed on the lower dielectric layer;

FIG. 5 is a cross-sectional side view of the assembly of FIG. 4, further including an upper dielectric layer formed on the diffusion barrier dielectric layer;

FIG. 6 is a cross-sectional side view of the assembly of FIG. 5, further including a lower conducting layer formed on the upper dielectric layer;

FIG. 7 is a cross-sectional side view of the assembly of FIG. 6, further including an upper conducting layer formed on the lower conducting layer;

FIG. 8 is a cross-sectional side view of the assembly of FIG. 7 after selectively etching the conducting and dielectric layers;

FIG. 9 is a cross-sectional side view of the assembly of FIG. 8, further including sidewalls around the conducting and dielectric layers, and doped source and drain regions in the silicon substrate; and

FIG. 10 is a cross-sectional side view of the assembly of FIG. 9, further including source, drain, and gate contacts.

### DETAILED DESCRIPTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

According to a first embodiment of the invention, the previously-described needs and others may be met by a semiconductor device that includes a substrate, a multilayered assembly of high k dielectric materials formed on the substrate, and a first conducting material formed on the upper layer of the assembly of high k dielectric materials. The multilayered high k dielectric assembly includes a lower layer, an upper layer, and one or more diffusion barrier layers formed between the lower and upper dielectric layers. The diffusion barrier layer has a greater affinity for oxygen than the upper and lower layers. The first conducting layer includes a conducting compound of at least a metal element and oxygen. According to another embodiment of the invention, an integrated circuit includes such a semiconductor device.

According to another embodiment of the invention, the above needs and others may be met by a method of manufacturing such a semiconductor device. The method includes forming the multilayered assembly of high k dielectric materials on the substrate, and forming the first conducting layer on the upper layer of the assembly of high k dielectric materials.

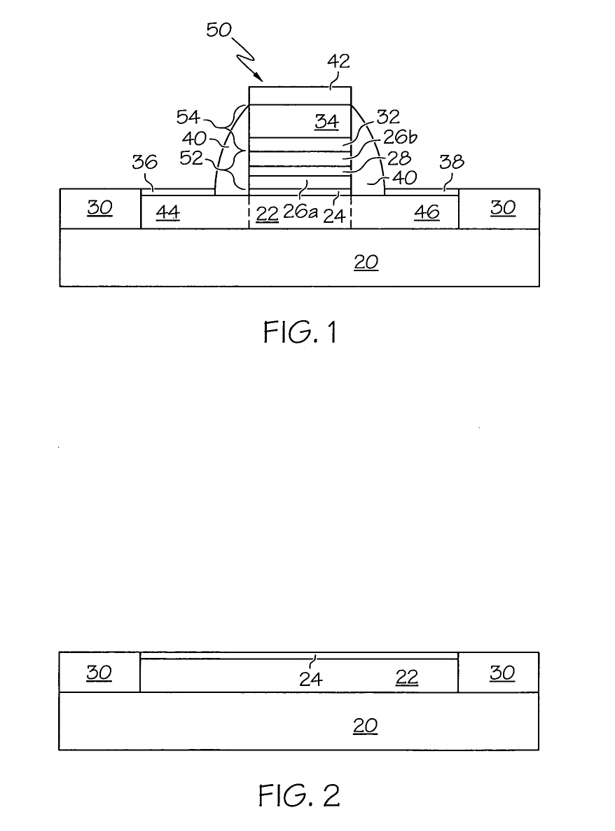

A cross-sectional side view of an exemplary semiconductor device is depicted in FIG. 1, the semiconductor device being a MOSFET. Although the figures represent an embodiment that includes an SOI transistor, the hereinafter described gate stack, can be also integrated with a bulk transistor or with a double-gated device such as a FinFET. The various layers depicted in FIG. 1 and the other drawings are not drawn to scale, but are emphasized or de-emphasized for sake of clarity.

A silicon layer 22 is disposed on a buried oxide layer BOX 20 between two shallow trench isolation (STI) structures 30 that are made from an insulating material such as TEOS (silicon dioxide). According to an exemplary embodiment, the BOX 20 supports the silicon layer 22 and integrated circuits or other circuitry and semiconductor devices formed thereon, and isolates the layer 22 and its circuitry from other electrical devices and/or circuitry. The BOX 20 may be located on a silicon substrate.

A gate stack 50 is disposed on the silicon layer 22 between a source region 44 and a drain region 46. The gate stack 50 comprises a thin silicon oxide film 24 formed on the silicon layer 22, a high k dielectric assembly 52 formed on the silicon layer 22, and a conductor assembly 54 formed on the high k dielectric assembly 52. A gate contact 42 covers the conductor assembly 54.

The conductor assembly 54 includes an upper layer 34 of a conducting material and a lower layer 32 of a conducting material, the lower layer 32 being formed over the high k dielectric assembly 52. An exemplary conducting material for the upper layer 34 includes a semiconducting material, such as polysilicon, that may be doped with a conducting metal or other conducting material such as nickel silicide (NiSi). The lower layer 32 includes a conductive metal oxide, oxynitride, oxysilicide, or another oxygen-containing metallic compound. Exemplary conducting materials for the lower layer 32 include molybdenum-based compounds including MoON and MoSiₓO_{y}., wherein x is in between 0 and 1 and y is between 0 and 2. The work function of the lower layer 32 determines the threshold voltage of the device. An exemplary lower layer 32 is between 50 Å and 250 Å in thickness; and an exemplary upper layer 34 is between 500 Å and 1000 Å in thickness.

The high k dielectric assembly 52 is formed over the thin silicon oxide film 24, and includes upper and lower layers, 26a and 26b, of a first dielectric material formed above and below an oxygen diffusion barrier layer 28 that includes a second dielectric material. Each of the upper and lower layers, 26a and 26b, may range between about 15 Å and about 200 Å. The oxygen diffusion barrier layer 28 may be as thin as about 5 Å, and may be up to about one half the thickness of the combined layers 26a and 26b.

An exemplary first dielectric material in layers 26a and 26b includes an insulating metal oxide, or a combination of two or more insulating metal oxides, having a dielectric constant higher than 3.9. Exemplary metal oxides that may be used as the first dielectric material include HfO₂ and mixed oxides such as ZrO₂/HfO₂. An exemplary second dielectric material in the oxygen diffusion barrier layer 28 includes an insulating metal oxide, or a combination of two or more insulating metal oxides. Other exemplary second dielectric materials include insulating metal silicates, metal aluminates, metal nitrides, metal nitrides, metal oxynitrides, and metal silicate nitrides. Further, the second dielectric material may be a combination of two or more insulating materials. The second dielectric material has a dielectric constant higher than 3.9, and also has a stronger affinity for oxygen than the first dielectric material. For example, if the first dielectric material in layers 26a and 26b is HfO₂, then the second dielectric material in the oxygen diffusion barrier layer 28 is an oxide that has a higher affinity to oxygen than HfO₂. Generally, metals that have a higher affinity to oxygen than Hf will form oxides that have a higher oxygen affinity than HfO₂. Listed in descending order with respect to their oxygen affinity, Y, Sc, Er, Ho, Lu, Tm, Th, Dy, Gd, Sm, Yb, Nd, Pr, Ce, La, and Eu have greater oxygen affinity than Hf, and their oxides have greater oxygen affinity than HfO₂. Other oxides having a relatively high oxygen affinity may be used as the second dielectric material. Further, the second dielectric material as a whole may be tailored to have an amorphous structure, or to have a lower oxygen concentration than dictated by stoichiometric proportions, in order to increase its affinity for oxygen.

Other exemplary second dielectric materials in layer 28 include non-oxide compounds, either in place of or in combination with high oxygen affinity metal oxides. For example, the second dielectric material may include high k metal silicates, metal aluminates, metal carbides, metal nitrides, metal oxynitrides, and other high k dielectric compounds. Regardless of the specific compound structure, the material in layer 28 is an insulating high k dielectric having a stronger oxygen affinity than the first dielectric material in layers 26a, 26b.

The silicon oxide film 24 is tailored to be as thin as 8 Å or less. An exemplary silicon oxide film 24 is about 4 Å in thickness. It is desirable to keep the silicon oxide film 24 thin because the measured k value of the overall dielectric is that of the silicon oxide film 24 and the high k dielectric assembly 52 in series. The oxide diffusion barrier layer 28 prevents formation of additional silicon oxide as an interfacial layer between the silicon oxide film 24 and the silicon layer 22. As previously discussed, when annealing the gate stack 50, some oxygen from the conducting material may have a tendency to leak through the dielectric layers 26a and 26b, and the thin silicon oxide film. Oxygen that leaks to the silicon substrate would form the interfacial silicon oxide layer and increase the effective oxide thickness for the overall dielectric material. By nature of its high oxygen affinity, the oxide diffusion barrier layer 28 keeps oxygen from leaking into the underlying dielectric layer 26a, and thus maintains the effective oxide thickness of the dielectric material, including the high k dielectric assembly 52 and the silicon oxide film 24. Further, the oxide diffusion barrier layer 28 improves the compatibility of high work function metal oxides, oxynitrides, oxysilicides, and other oxygen-containing metallic compounds with high k dielectric materials, and thereby improves the reliability of MOSFETs that include such conducting materials.

A gate contact layer 42 covers the conductor assembly 54. A source contact layer 36 and a drain contact layer 38 are formed over the source region 44 and the drain region 46, respectively, in the silicon layer 22. The contact layers 36, 38, and 42 may be formed from the same or different materials, and are preferably formed from a conductive metal such as copper. Typically, the contact layers 36, 38, 42 are formed over barrier layers with core metals such as W or Cu formed therethrough as contact vias to allow selected regions of the conductor assembly 54, the source region 44, and the drain region 46 to be contacted. The entire contact structures are not shown in the drawings but are well understood by those skilled in the art. Spacers 40 formed astride the gate stack 50 separate it from the source contact 36 and the drain contact 38. The spacers 40 are formed from an insulating material such as silicon nitride or silicon dioxide.

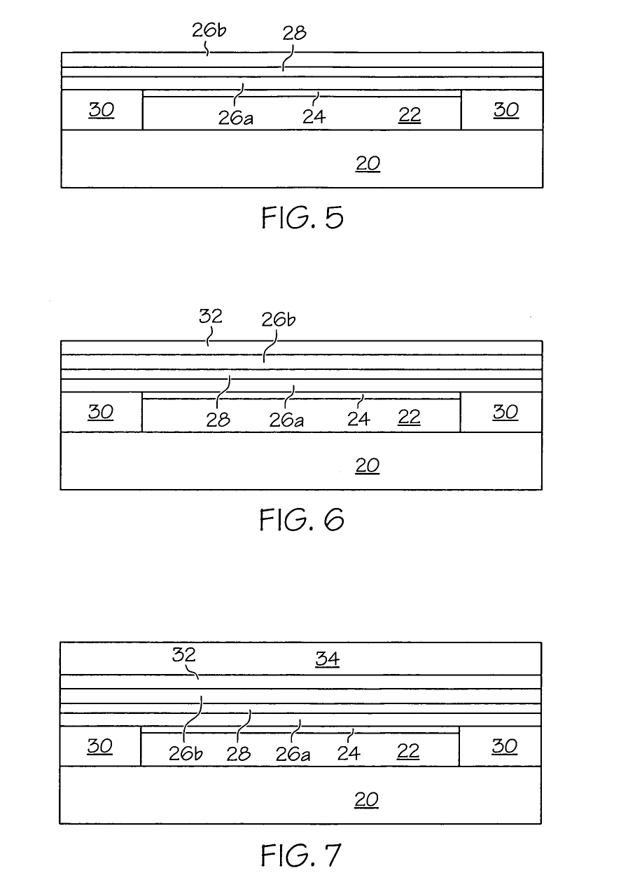

Having described an exemplary gate structure, a method of manufacturing a MOSFET that includes the gate stack 50 is described next with reference to FIGS. 2 to 10, which are cross-sectional side views of a BOX 20 between two shallow isolation trenches 30, and MOSFET materials as they are formed thereon.

Beginning with FIG. 2 , a silicon oxide film 24 is grown on the silicon layer 22. A native oxide layer may already be present on the silicon layer 22 since silicon is readily oxidized in the presence of air or another oxygen source. According to an exemplary embodiment, any native oxide is etched or otherwise removed from the silicon layer 22 so the silicon oxide film 24 may be grown in a controlled manner with a predetermined thickness and stoichiometry.

The silicon oxide film 24 may be grown by placing the box 20 including the silicon layer 22 into an oxidizing atmosphere at an elevated temperature. Exemplary oxidizing gases include water vapor, oxygen, oxygen diluted with nitrogen, various nitrogen-oxygen compounds, and various carbon-oxygen compounds. The oxidizing atmosphere is selected based on various factors such as the desired film density and the desired speed of oxidation. For example, cooler and/or drier oxygen will cause the silicon oxide film 24 to grow relatively slowly, while hotter and/or wet oxygen or water vapor oxidizes the silicon layer 22 more quickly. Also, the nitrogen-oxygen and carbon-oxygen compounds tend to enable growth of a thin oxide. Oxidation temperatures range between about 700° C. and 1250° C., and are preferably between about 900° C. and 1000° C.

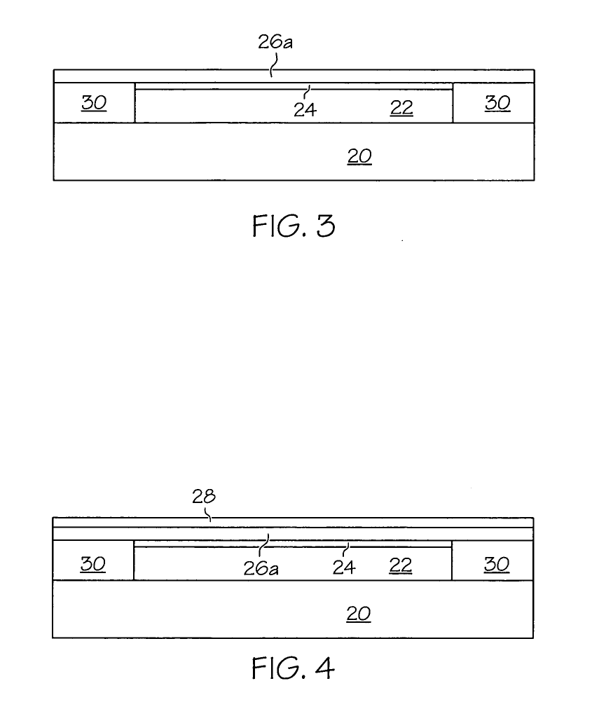

FIGS. 3 to 5 collectively illustrate steps for forming the high k dielectric assembly layers, which include the lower and upper layers, 26a and 26b, of a first dielectric material formed above and below the dielectric oxygen diffusion barrier layer 28 as previously discussed with reference to FIG. 1. According to one exemplary embodiment, a metal oxide having a dielectric constant higher than 3.9, or a combination of two or more of such metal oxides, is deposited onto the silicon oxide film 24 to form the lower dielectric layer 26a. The oxygen diffusion barrier layer 28, having a higher oxygen affinity than the lower and upper dielectric layers, 26a and 26b, is then deposited onto the lower dielectric layer 26a. Thereafter, the upper dielectric layer 26b is formed by depositing another layer of the metal oxide having a dielectric constant higher than 3.9 onto the oxygen diffusion barrier layer 28. In an exemplary embodiment, the lower and upper dielectric layers, 26a and 26b, are formed from the same metal oxide or combination of metal oxides, although they may also be formed from different materials. Some suitable deposition techniques for forming the lower layer 26a, the oxygen diffusion barrier layer 28, and the upper layer 26b include atomic layer deposition (ALD), physical vapor deposition (PVD), and chemical vapor deposition (CVD) including low pressure CVD (LPCVD) and plasma enhanced CVD (PECVD).

FIGS. 6 to 7 collectively illustrate steps for forming the conductor assembly layers, which include the upper conducting layer 34 and the lower conducting layer 32, which is formed over the high k dielectric assembly 52 as previously discussed with reference to FIG. 1. A conductive metal oxide, oxynitride, oxysilicide, or another oxygen-containing metallic compound is deposited onto the upper dielectric layer 26b to form the lower conducting layer 32. Then, the upper conducting layer 34 is formed over the lower conducting layer 32 by depositing a doped semiconducting material, such as doped polysilicon or another conducting material. Some suitable deposition techniques for forming the upper and lower conducting layers, 32 and 34 include PVD, CVD, and ALD.

As depicted in FIG. 8, the silicon oxide layer 24, the high k dielectric assembly layers 26a, 26b, and 28, and the conductor assembly layers 32 and 34 are patterned. An exemplary method of patterning such layers is to selectively deposit photoresist over the upper conducting layer 34, followed by applying an etchant so the exposed portions of the upper conducting layer 34 are removed. An anisotropic etching process will enable the layers underlying the upper conductor layer 34 to be etched without significant erosion to the portions that are covered with photoresist. Plasma etchant species are particularly capable of anisotropic etching. Reactive ion etching is one exemplary process by which ions can be directed vertically to strike the layers substantially perpendicular to the layer surfaces. After performing an etching process, the remaining photoresist is removed using a liquid etchant, an oxygen-containing plasma, or another removal procedure.

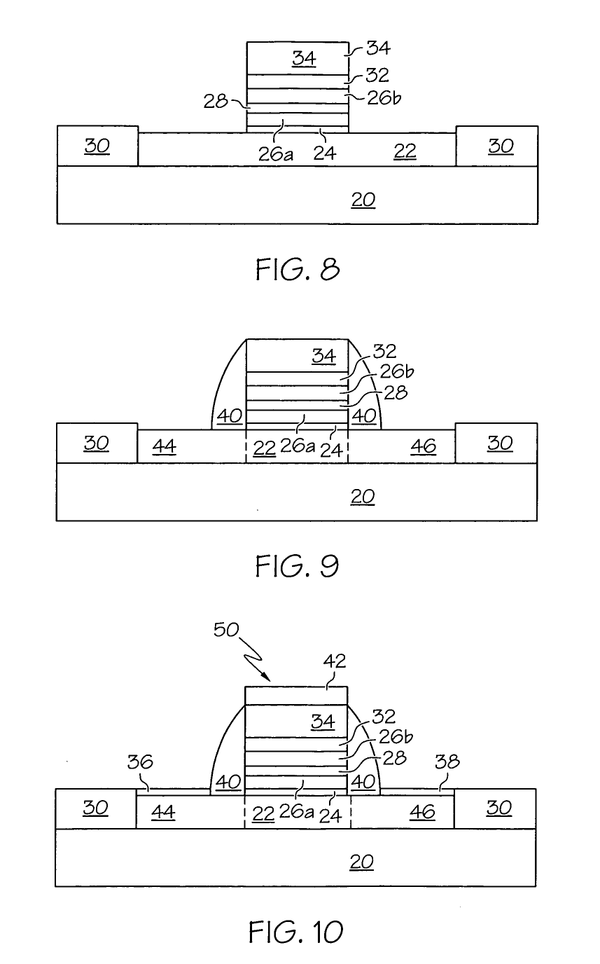

Next, spacers 40 are formed astride the dielectric and conducting layers as depicted in FIG. 9. The spacers 40 are formed from an insulating material such as a silicon oxide, or silicon nitride. Etching procedures may be used to shape the spacers 40. With the spacers 40 off-setting the implantation from the gate stack edges, dopants are directed into exposed regions of the silicon layer 22 to form the source 44 and the drain 46. Some embodiments may include source or drain extensions as well.

To electrically activate the dopant ions, the assembly is annealed at a temperature of at least a 600° C. The anneal also heals any disruptions to the silicon crystal lattice resulting from the dopant. The heat allows atoms to migrate to crystal substitutional sites rather than remain in interstitial positions. An exemplary process is a rapid thermal annealing (RTA). In RTA the temperature is rapidly spiked to the annealing temperature using a heat source such as a bank of infra red heat lamps. As previously discussed, during a high temperature annealing process, a nonmetal element such as oxygen from the lower conducting layer 32 may leak into the dielectric upper layer 26b. If the oxygen were to leak through the lower dielectric layer 26a, and then through the thin silicon oxide layer 24, a reaction with the silicon layer 22 would cause the growth of an additional interfacial silicon oxide layer between the layer 22 and the thin silicon oxide layer 24. The interfacial layer would detrimentally increase the effective oxide thickness for the combined silicon oxide layer 24 and the high k dielectric assembly 52. Since the diffusion barrier layer 28 has a higher affinity for the nonmetal element than the upper or lower dielectric layers 26a and 26b, the nonmetal is retained by the diffusion barrier layer 28 and the effective oxide thickness is controlled.

After annealing the assembly, contact layers 36 and 38 are formed over the source 44 and the drain 46 as depicted in FIG. 10. Likewise, the gate stack 50 is completed by forming a gate contact layer 42 over the upper conductor layer 34. An exemplary contact material is a conductive metal such as cobalt or nickel silicides.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing the exemplary embodiment or exemplary embodiments. It should be understood that various changes can be made in the function and arrangement of elements without departing from the scope of the invention as set forth in the appended claims and the legal equivalents thereof.

1. A semiconductor device, comprising:
a substrate;
a multilayered assembly of high k dielectric materials formed on the substrate, the multilayered assembly comprising:
a lower layer,
an upper layer, and
at least one diffusion barrier layer formed between the lower and upper dielectric layers, the at least one diffusion barrier layer having a greater affinity for oxygen than the upper and lower layers; and
a first conducting layer formed on the upper layer of the assembly of high k dielectric materials, the first conducting layer comprising a conducting compound that includes at least a metal element and oxygen.

2. The semiconductor device according to claim 1, wherein the first conducting layer comprises at least one compound selected from the group consisting of a conductive metal oxide, a conductive metal oxynitride, and a conductive metal oxysilicide.

3. The semiconductor device according to claim 1, wherein the upper and lower high k dielectric layers comprise a hafnium compound.

4. The semiconductor device according to claim 3, wherein the diffusion barrier layer comprises a compound including at least one metal having a greater affinity for oxygen than hafnium, the at least one metal selected from the group consisting of Y, Sc, Er, Ho, Lu, Tm, Tb, Dy, Gd, Sm, Yb, Nd, Pr, Ce, La, and Eu.

5. The semiconductor device according to claim 1, further comprising:
a second conducting layer formed on the first conducting layer, the second conducting layer comprising doped polysilicon.

6. The semiconductor device according to claim 1, further comprising:
a silicon oxide layer grown on the substrate beneath the multilayered assembly of high k dielectric materials.

7. The semiconductor device according to claim 1, wherein the at least one diffusion barrier layer has an amorphous structure.

8. The semiconductor device according to claim 1, wherein the at least one diffusion barrier layer has a stoichiometric oxygen deficiency.

9. The semiconductor device according to claim 1, wherein the at least one diffusion barrier layer is formed at a thickness of up to about half of the thickness of the combined upper and lower high k dielectric layers.

10. The semiconductor device according to claim 1, wherein the at least one diffusion barrier layer comprises at least one compound selected from the group consisting of a metal silicate, a metal aluminate, a metal carbide, a metal nitride, and a metal oxynitride.

11. An integrated circuit, comprising the semiconductor device according to claim 1.

12. A method of manufacturing a semiconductor device, comprising:
forming a multilayered assembly of high k dielectric materials on a substrate, the multilayered assembly comprising:
a lower layer;
an upper layer; and
at least one diffusion barrier layer formed between the lower and upper layers, the at least one diffusion barrier layer having a greater affinity for oxygen than the upper and lower layers; and
forming a first conducting layer on the upper layer of the assembly of high k dielectric materials, the first conducting layer comprising a conducting compound that includes at least a metal element and oxygen.

13. The method according to claim 12, wherein the first conducting layer comprises at least one compound selected from the group consisting of a conductive metal oxide, a conductive metal oxynitride, and a conductive metal oxysilicide.

14. The method according to claim 12, wherein the upper and lower dielectric layers comprise a hafnium compound.

15. The method according to claim 14, wherein the at least one diffusion barrier layer comprises a compound including at least one metal having a greater affinity for oxygen than hafnium, the at least one metal selected from the group consisting of Y, Sc, Er, Ho, Lu, Tm, Tb, Dy, Gd, Sm, Yb, Nd, Pr, Ce, La, and Eu.

16. The method according to claim 12, further comprising:
forming a second conducting layer on the first conducting layer, the second conducting layer comprising doped polysilicon.

17. The method according to claim 12, wherein the diffusion barrier layer is formed having an amorphous structure.

18. The method according to claim 12, wherein the diffusion barrier layer is formed having a stoichiometric oxygen deficiency.

19. The method according to claim 12, wherein the diffusion barrier layer is formed at a thickness of up to about half of the thickness of the combined upper and lower layers.

20. The method according to claim 12, wherein the diffusion barrier layer comprises at least one compound selected from the group consisting of a metal silicate, a metal aluminate, a metal carbide, a metal nitride, and a metal oxynitride.
